(19) United States
(12) Patent Application Publication
(10) Pub. No.: US 2011/0247690 A1
(43) Pub. Date: Oct. 13, 2011

(54) SEMICONDUCTOR DEVICES COMPRISING ANTIREFLECTIVE CONDUCTIVE LAYERS AND METHODS OF MAKING AND USING

(76) Inventors: David Thomas Crouse, New York, NY (US); Thomas L. James, Newy York, NY (US); Michael M. Crouse, East Greenbush, NY (US)

(21) Appl. No.: 13/140,806

(22) PCT Filed: Dec. 17, 2009
(86) PCT No.: PCT/US09/68413

§ 371 Date: Jun. 17, 2011

(30) Foreign Application Priority Data
Dec. 17, 2008 (US) 61/201981

(51) Int. Cl. H01L 31/0224; H01L 31/0232; H01L 23/48; H01L 21/20; H01L 21/28

(52) U.S. Cl. 136/256; 438/382; 438/669; 257/786; 257/E23.01; 257/E21.09; 257/E21.158

(57) ABSTRACT

A semiconductor device includes a semiconductor substrate and an antireflective conductive layer. The antireflective conductive layer includes a metal layer disposed on the semiconductor substrate and defining at least one array of apertures through the metal layer. Each of the apertures has a width of no more than 5 μm and a distance between each aperture and its nearest neighboring aperture is no more than 10 μm. The antireflective conductive layer also includes a solid material filling each of the apertures, wherein the solid material has an index of refraction of at least 1.1.

### CROSS REFERENCE TO RELATED APPLICATIONS

The present application claims the benefit of U.S. Provisional Patent Application Ser. No. 61/201,981, filed Dec. 17, 2008, which is hereby incorporated by reference in its entirety.

### FIELD

The invention is directed to semiconductor devices that include an antireflective conductive layer and methods of making and using the devices. The invention is also directed to solar cells that include an antireflective conductive layer and methods of making and using the devices.

### BACKGROUND

Light-reactive semiconductor devices have a number of applications. One of the primary examples of a light-reactive semiconductor device is a solar cell. light of the current energy crisis and concerns about global warming, the development of higher-performance lower-cost solar cells has become increasingly important to national economic and security needs, However, throughout the decades of research on solar cells, solutions to fundamental technical problems have been incremental in nature and the goal of highly efficient but inexpensive solar cells has proven to be elusive. Conventional single junction silicon solar cells which currently dominate the solar cell market have low conversion efficiencies of approximately 15%. There is a need to find device structures and methods that increase these efficiencies.

### BRIEF SUMMARY

One embodiment is a solar cell that includes a semiconductor substrate and an antireflective conductive layer. The antireflective conductive layer includes a metal layer disposed on the semiconductor substrate and defining at least one array of apertures through the metal layer. Each of the apertures has a width of no more than 5 μm and a distance between each aperture and its nearest neighboring, aperture is no more than 10 μm. The antireflective conductive layer also includes a solid material filling each of the apertures, wherein the solid material has an index of refraction of at least 1.1.

Another embodiment is a method of making an antireflective conductive layer on a substrate. The method includes forming a first layer of a first material on the substrate. The first material is non-conductive or semiconductive. The first layer is patterned to form a plurality of posts from the first layer and expose the substrate between the posts. Each of the posts has a width of no more than 5 μm and a distance between each post and its nearest neighboring post is no more than 10 μm. A metal layer is formed over the exposed substrate and the plurality of posts. A portion of the metal layer is removed to expose ends of the plurality of posts and form the antireflective conductive layer.

A further embodiment is a method of making an antireflective conductive layer on a substrate. The method includes forming a metal layer on the substrate and then patterning the metal layer to form a plurality of apertures through the metal layer and exposing, the substrate through the apertures. Each of the apertures has a width of no more than 5 μm and a distance between each apertures and its nearest neighboring aperture is no more than 10 μm. The apertures are filled with a first material that is non-conductive or semiconductive.

Yet another embodiment is a semiconductor device that includes a semiconductor substrate and an antireflective conductive layer. The antireflective conductive layer includes a metal layer disposed on the semiconductor substrate and defining at least one array of apertures through the metal layer. Each of the apertures has a width of no more than 5 μm and a distance between each aperture and its nearest neighboring aperture is no more than 10 μm. The antireflective conductive layer also includes a solid material filling each of the apertures, wherein the solid material has an index of refraction of at least 1.1.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified,

For a better understanding of the present invention, reference will be made to the following Detailed Description, which is to be read in association with the accompanying drawings, wherein:

FIG. 1A is a schematic perspective view of one embodiment of a semiconductor device with an antireflective conductive layer, according to the invention;

FIG. 1B is a schematic diagram of one embodiment of a solar cell with an antireflective conductive layer, according to the invention;

FIG. 2 is a graph of a transmission curve for an antireflective conductive layer disposed on silicon, according to the invention:

FIG. 3 is schematic perspective illustration of a unit cell with two apertures in the antireflective conductive layer, according to the invention;

FIG. 4 is a schematic illustration of a method of making an antireflective conductive layer on a substrate, according to the invention;

FIG. 5 is a scanning electron microscope image of one embodiment of an antireflective conductive layer, according to the invention; and

FIG. 6 is a scanning electron microscope image of a second embodiment of an antireflective conductive layer, according to the invention.

### DETAILED DESCRIPTION

The invention is directed to semiconductor devices that include an antireflective conductive layer and methods of making and using the devices. The invention is also directed to solar cells that include an antireflective conductive layer and methods of making and using the devices. The antireflective conductive layer uses properties of one or more of surface plasmons, plasmonic crystals, and optical cavity modes to increase light collection. For solar cell applications, for example, this can increase solar cell conversion efficiency. Plasmonic and photonic crystals effects that are particularly useful include optical cavity modes, surface plasmons, Rayleigh anomalies, and diffraction.

A broadband antireflective conductive layer for a semiconductor device can be made using a metal layer (e.g., a film) with an array of small apertures formed through the metal layer and filled with a dielectric material or other nonconductive or semiconductor material. This antireflective conductive layer can be used for a variety of semiconductor devices, including solar cells, photodetectors, light emitting diodes, lasers, and other opto-electronic integrated devices. In at least some embodiments, the antireflective conductive layer is substrate independent. For example, the antireflective conductive layer can be fabricated atop any substrate of relevance to the solar cell industry including, but not limited to, crystalline silicon, polycrystalline silicon, amorphous silicon, CdTe, CIGS and any III-V semiconductor material used in multi-junction solar cells. With minor alterations to feature dimensions, the antireflective conductive layer can be tuned to transmission wavelengths and bandwidths to suit the absorbing wavelength range of any substrate.

The antireflective conductive layer can be a photonic-plasmonic crystal film that serves multiple functions, such as: 1) a high-performance antireflective coating, 2) an “invisible electrode,” that can serve as a top electrical contact, 3) a light scatterer such that the light transmitted into the substrate is scattered over large angles, and 4) a wavelength filter and efficient heat-conducting material that can reduce substrate heating. The antireflective conductive layer uses the phenomenon of anomalous optical transmission (AOT) to make antireflecting electrical contacts over the entire surface of the solar cell or other semiconductor device that have the high conductivity of a metal and the antireflection characteristics of a dielectric film stack (e.g., >85% transmissive) across a wide range of the solar spectrum (e.g., 400 nm-1.2 μm) or subbands within the 400 nm-1.2 μm spectral band and for a wide range of angles of incidence (e.g., 0° to 45°). The invisible electrodes can be used on any substrate and in conjunction with solar concentrators, as the high transmission is not highly dependent of angle of incidence.

The antireflective conductive layer can act as a light collector and transmitter, as well as a contact for a semiconductor device, if desired. As an example of possible benefits for at least some embodiments, these antireflective conductive layers can improve solar cell efficiency by achieving one or more of the following:

1. Maintaining or increasing the percentage of incident light transmitted into the absorbing semiconductor to greater than 85%, as compared to approximately 85-90% for current antireflective coatings;

2. Decreasing the number of charge-trapping grain boundaries through which charge carriers travel prior to reaching electrical contacts (particularly in the case of multicrystalline silicon solar cells);

3. Efficiently scattering the transmitted light within the absorbing semiconductor to facilitate uniform absorption and increase the effective absorption pathlength;

4. Reducing harmful heating of the substrate, which can cause efficiency reductions (in at least some embodiments, the antireflective conductive layers are selected to filter out, or at least partially reflect, high and low wavelength radiation that would not be efficiently converted to electrical energy but would only heat up the substrate); and

5. Functioning as a high heat-conducting layer to transport heat to the periphery of the device.

The antireflective conductive layer uses an array of horizontally distributed apertures in a metal layer, with each aperture designed to produce surface plasmons, optical cavity modes, or both across a broad wavelength range. Preferably, the apertures are designed to produce optical cavity modes. The wavelength range can be, for example, from 400 to 1200 nanometers, 600 to 1200 nanometers, 400 to 1100 nanometers, 600 to 1100 nanometers, or any other or smaller wavelength band within the 400 to 1200 nanometers wavelength band. In other embodiments, the wavelength range may include wavelengths in the infrared region or the range may be entirely within the infrared region. In some embodiments, the antireflective conductive layer allows for very high (for example, at least 80%, 85%, 90%) or 95%) transmission of light of a given broad wavelength range (e.g., 400 to 1200 nm or 600 to 1100 nm) through the horizontally distributed aperture array. Most of the tight within a selected wavelength range will be transmitted through the apertures. In some embodiments, much or most of the light outside the desired wavelength range is preferably reflected.

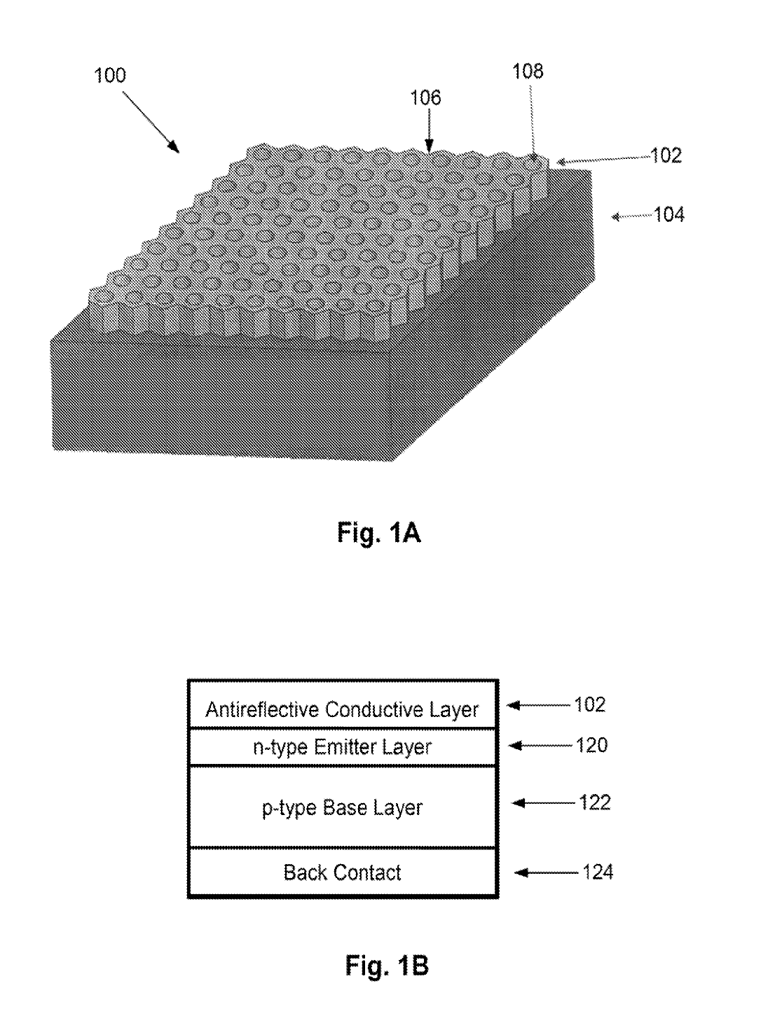

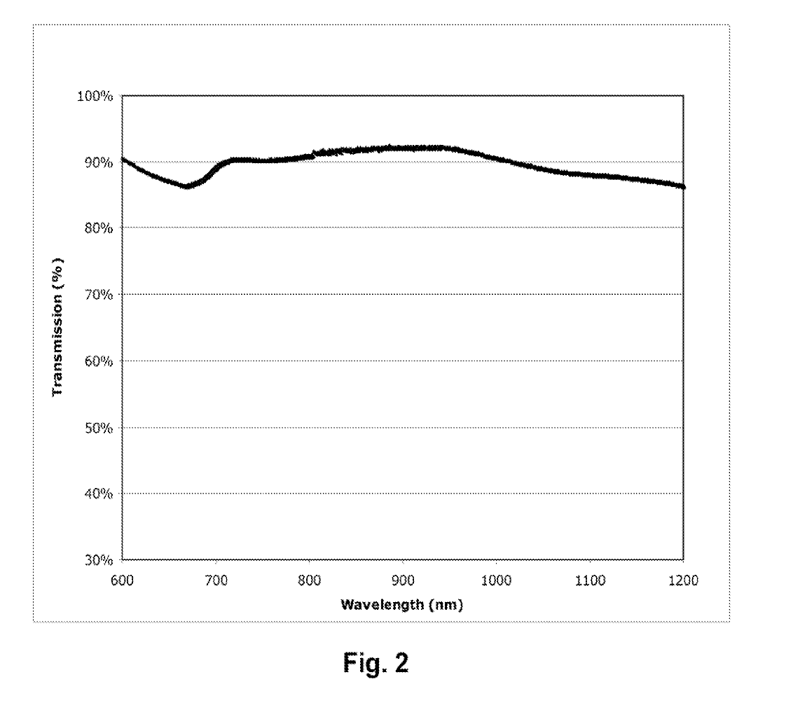

FIG. 1A schematically illustrates one embodiment of a portion 100 of a semiconductor device with an antireflective conductive layer 102 disposed on a substrate 104. The antireflective conductive layer 102 includes a metal layer 106 with an array of apertures 108 through the metal layer. FIG. 1B is a schematic diagram of one embodiment of a solar cell device which includes the antireflective conductive layer 102, an n-type emitter layer 120, a p-type base layer 122, and a back contact 124. The substrate of FIG. 1A can correspond to, for example, layer 120, 122 of FIG. 1B. FIG. 2 illustrates a measured transmission curve 200 for an antireflective conductive layer on a silicon substrate. The anomalous transmission of light allows more than 85% transmittance (total power out/total power in) into the underlying substrate.

The apertures can have any suitable shape and size and can be uniform in shape and size or can have different shapes, sizes (e.g., depth, width, or both), or both. For example, the apertures can be cylindrical in shape. In other embodiments, the apertures can have a lateral cross-sectional shape that is elliptical, rectangular, square, bowtie, hexagonal, co-axial (i.e., an annulus), or any other regular or irregular shape. The shape of the apertures, however, should support surface plasmons, optical cavity modes, or both within the aperture cavity.

In at least some embodiments, the lateral cross-sectional shape of the apertures can affect the polarization dependence of transmission. For example, in at least some embodiments, a circular or square lateral cross-sectional shape provides polarization independence of the transmission. On the other hand, using rectangular, elliptical, or bow-tie shaped apertures can provide polarization dependence in the transmitted light.

The metal layer of the antireflective conductive layer can be selected from any suitable metal or combination (e.g., alloy or mixture) of metals. For example, the metal layer may be made of aluminum, gold, silver, copper, titanium, tungsten, tin, lead, or any combination thereof, or alloys of these metals with some fraction of silicon (e.g., aluminum-silicon alloy).

The metal layer can have any suitable thickness. The thickness of the metal layer typically also corresponds to the depth of the apertures. In some embodiments, the thickness of the metal layer (or depth of the apertures) is no more than 5 μm, 2 μm, or 1 μm. In some embodiments, the thickness of the metal layer is at least 50 nm, 100 nm, 200 nm, or 500 nm. In some embodiments, the thickness of the metal layer (or depth of the apertures) is in the range of 50 nm to 5 μm; or in the range of 200 or to 2 μm. In some embodiments, the depth of the apertures is related, to a designed wavelength of operation, which is a wavelength with the high transmission wavelength band of the antireflective conductive layer and may be the central wavelength of the band. Typically, the depth of the apertures is in the range of λ/4 n to 4λ/n, where n is the index of refraction of the material filling the apertures.

In some embodiments, a width (e.g., a diameter, length, or other lateral dimension) of the apertures may be related to the designed wavelength of operation, λ, which is a wavelength with the high transmission wavelength band of the antireflective conductive layer. Typically, the width of the apertures is in the range of λ/4 n to 4λ/n, where n is the index of refraction of the material filling the apertures.

In at least some embodiments, the apertures have widths (e.g., diameters in the case of cylindrical cavities, or major and minor axes lengths in case of elliptical cavities, or widths and breadths in the case of rectangular or square cavities) in the range of 50 nm to 5 μm, or in the range of 200 nm to 2 μm. In some embodiments, the width of the apertures is no more than 5 μm, 2 μm, or 1 μm. in some embodiments, the width of the apertures is at least 50 nm, 100 nm, 200 nm, or 500 nm.

In at least some embodiments, the aspect ratio of aperture depth/width influences the bandwidth of high light transmission. The smaller the value of the aspect ratio, the larger the bandwidth. In some embodiments, the aspect ratio (depth/width) is no more than 5, 4, 3, or 2. In some embodiments, the aspect ratio (depth/width) is at least 0.2, 0.5, or 1. In some embodiments, the aspect ratio (depth/width) is in the range of 0.2 to 5, or in the range of 0.5 to 4, or in the range of 1 to 3.

The dimensions of the apertures are chosen to produce surface plasmons on the wall of the cavity, optical cavity modes within the aperture cavity, or both, which act as a light whirlpool, pulling light (of a certain wavelength band) from areas distant from the cavity into and through the cavity. Preferably, the apertures produce optical cavity modes within the aperture cavity. The aperture dimensions can vary depending on factors, such as, for example, i) whether primarily surface plasmons or primarily optical cavity modes are used to produce this effect, ii) the material used to fill the aperture cavity, iii) the substrate material upon which the antireflective conductive layer is fabricated (i.e., the material underneath the aperture into which light flows after it passes through the aperture), and iv) the spectral band of operation of the solar cell.

The apertures can be filled with air, an insulator material, or a semiconductor material. For example, the apertures can be filled with glass, polymer, photoresist, polyimide, silicon dioxide, silicon, silicon nitride, silicon oxynitride, hafnium oxide, ditantalum pentoxide, or some other glass, oxide or semiconductor material. Preferably, the apertures are filled with a solid dielectric. In at least some embodiments, the apertures are filled with a solid dielectric having a dielectric constant of at least 1.1, 1.5, 2, 2.5, 3, 4, 5, 10, or 13. In some embodiments, the apertures are filled with a solid dielectric having a dielectric constant in the range of 2 to 8; 2.5 to 6; or 3 to 13. Preferred dielectric materials include, but are not limited to, silicon oxynitride, silicon dioxide, and polysilicon.

The apertures can be provided in any regular or irregular array. For example, the configuration of the array can be a simple square lattice, hexagonal lattice, rectangular lattice or some other periodic lattice, or a repeating but not periodic array (e.g., an aperiodic Penrose array), or a nonperiodic array, or a random or pseudo-random array. Aperiodic arrays, random or pseudo-random and nonperiodic arrays may be useful to lessen the effects of Fraunhofer diffraction, or to produce focusing or collimation characteristics.

The spacing of the apertures (e.g., the size of a unit cell in a periodic array) can influence the transmission characteristics of the antireflective conductive layer. In some embodiments, the spacing of the apertures (e.g., the distance between an aperture and its nearest neighbor aperture) may be related to the designed wavelength of operation, λ, which is a wavelength with the high transmission wavelength band of the antireflective conductive layer. Typically, the width of the apertures is in the range of λ/4 n to 5λ/n, where n is the index of refraction of the material filling the apertures. If no Fraunhofer diffraction is desired, then preferably the spacing is less than λ/n, where n is the index of refraction of the substrate or a top layer above the metal.

In at least some embodiments, the apertures can have spacings (e.g., the size of a unit cell in a periodic array) in the range of 100 nm to 10 μm; or in the range of 250 nm to 2 μm. In some embodiments, the spacing between the apertures is no more than 10 μm, 5 μm, or 2 μm. In some embodiments, the spacing between the apertures is at least 100 nm, 200 nm, 400 nm, or 700 nm.

In some embodiments, the antireflective conductive layer may include multiple, overlapping arrays of apertures with different widths, different shapes, or both. Providing apertures with different widths can increase the transmission bandwidth of the antireflective conductive layer. Apertures with different widths can be distributed randomly or in periodic or aperiodic arrays. In these embodiments, the unit cell of the array typically includes two, three, four, or more apertures.

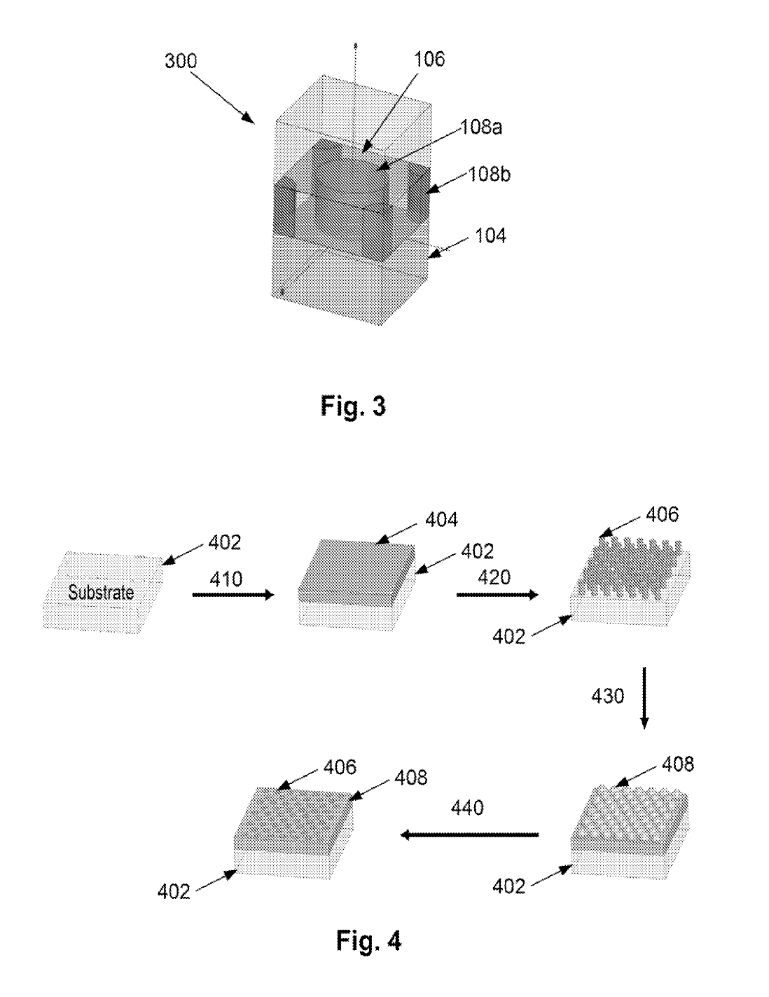

For example, in some embodiments, there are two sets of apertures, each set of apertures having a different width. In some embodiments, the width of the first set of apertures is at least 50 nm, 100 nm, 200 nm, 500 nm, 1 μm, or 2 μm less than the width of the second set of apertures. FIG. 3 illustrates one example of a unit cell 300 with two apertures 108a, 108b of different widths and formed through the metal layer 106 on the substrate 104.

When more than one aperture is in each unit cell, such as two, three or more apertures per unit cell, several optical effects may occur. As described above, each aperture in the unit cell can be designed (e.g., by selecting different aperture widths) to channel and transmit light of different wavelengths. When light of a range of wavelengths is incident on the film, the light falling on each unit cell is split with light with different subsets of wavelengths are channeled to and through the different apertures. On the other hand, there are many optical effects that can occur in these structures and it is not immediately apparent that having two apertures per unit cell arrays will lead to similarly large transmission values but throughout a broader wavelength range when compared to arrays with a single aperture per unit cell. It is typically thought that by adding other apertures in each unit cell, the transmission will be decreased for particular wavelengths; but it has been found in the development of the invention described herein that high transmission can be maintained by careful design of the array.

For example, one effect that sometimes occurs in compound aperture arrays (i.e., arrays with more than one aperture per unit cell) are phase resonances, also called coupled cavity effects, in which light that is channeled through one aperture in each unit cell, turns around and is goes back through the layer through a different aperture in the unit cell. These phase resonances cause a sharp decrease in transmission. One way to mitigate or eliminate these undesirable phase resonances is to lower the aspect ratio of the apertures and space the different apertures in each unit cell further apart.

It will be recognized that the antireflective conductive layer can be formed on a variety of substrates, including the semiconductor substrates described above. For example, the substrate can be any material that is either rigid or flexible including, but not limited to, glass, quartz, fused silica, silicon, plastic or other polymer material or any other material or crystalline silicon, polycrystalline silicon, amorphous CdTe, CIGS and any III-V semiconductor material. The substrate can have any suitable thickness. For example, the thickness of the substrate can be in the range of 50 nm to 10 cm.

The substrate of many semiconductor devices, including solar cells, includes at least one junction (e.g., a p-n junction) or is part of a junction. For example, the substrate of the antireflective conductive layer 102 in FIG. 1B can be the n-type emitter layer 120, the p-type base layer 122, or the combination of both The substrate is also typically coupled to one or more contacts (e.g., back contact 124 of FIG. 1B). In addition, as indicated above the antireflective conductive layer can operate as a contact for the device.

There can either be i) no layers between the substrate and antireflective conductive layer, or ii) one or multiple layers between the substrate and antireflective conductive layer and serving different purposes including, but not limited to, adhesion promoter, electrical contacts, eliminate deleterious reactions or intermixing of materials in the structure or other purposes. These layers can be of thicknesses between 0.1 nm to 1 μm and can be composed of, for example, platinum, titanium, tantalum, aluminum, chrome, silicon dioxide, polycrystalline silicon, silicon nitride, copper or any alloy or mixture of these materials or any other conductive or insulating materials.

In designing an antireflective conductive layer there are a number of considerations. In at least some embodiments, increasing the aperture depth results in higher Q (i.e., quality factor) apertures with lower bandwidths and lower transmission efficiencies. In at least some embodiments, increasing the aperture width leads to lower wavelength transmission peaks and higher transmission efficiencies. This may occur in part because the area of the aperture itself increases and so it receives more light. In at least some embodiments, increasing the period of an array, while holding aperture dimensions constant, can lead to a decrease in average transmission efficiencies.

In at least some embodiments, the antireflective conductive layer can be formed using conventional semiconductor processing techniques. The following is an example of one method. The method is schematically illustrated in FIG. 4. A substrate 402 (for example, a semiconductor substrate such as a silicon wafer) is coated with a first layer 404 made of the material that will fill the apertures (for example, silicon oxynitride) (step 410). The coating of the substrate can be performed using any suitable technique including, but not limited to, spin coating, chemical or physical vapor deposition (e.g., plasma enhanced chemical vapor deposition, sputtering, or evaporation), and the like.

The first layer 404 is patterned to produce an array of posts 406 on the substrate 402 (step 420). The patterning can be performed using any suitable technique including, but not limited to, photolithography, e-beam lithography, imprint lithography, etching (e.g., chemical etching, reactive ion etching), co-block polymer self-assembly and the like.

A metal layer 408 (e.g., aluminum) is then deposited over the substrate 402 and array of posts (step 430). Again, any suitable deposition technique can be used including, but not limited to physical vapor deposition (e.g., sputtering or evaporation), electrodeposition and the like.

The surface can then be planarized to remove the metal over the array of posts 406, thereby exposing the posts (which correspond to the array of apertures) (step 440). Any suitable technique can be used including, but not limited to, chemical mechanical polishing, etchback planarization using reactive ion etches, wet etches or electrochemical etches, and the like.

Alternatively, a lift-off procedure can also be used to remove the metal. In this procedure, the first layer is patterned using a resist layer that is formed and patterned over the first layer. The patterning of the resist layer leaves portions of the resist layer over the portions of the first layer that will form the posts. These portions of the resist layer are left over the posts after forming the posts. After deposition of the metal layer, organic solvent can be used to dissolve the resist over the posts, which also results in the removal of the metal over the posts as well.

In another alternative method of making the antireflective conductive layer, a metal layer is disposed first on the substrate. Any suitable deposition technique can be used including, but not limited to, physical vapor deposition (e.g., sputtering or evaporation), electrodeposition, and the like.

The metal layer is patterned to produce an array of apertures. The patterning can be performed using any suitable technique including, but not limited to, photolithography, e-beam lithography, imprint lithography, etching (e.g., chemical etching, reactive ion etching), and the like.

The apertures are then filled with a non-conductive or semiconductor material. The apertures can be filled by, for example, spin coating, chemical or physical vapor deposition (e.g., plasma enhanced chemical vapor deposition, sputtering, or evaporation), and the like. In at least some embodiments, the material filling the apertures will also cover the top surface of the metal layer during this stage of the procedure.

The surface can then be planarized to expose the metal layer leaving the apertures filled. Any suitable technique can be used including, but not limited to, chemical mechanical polishing, etchback planarization using reactive ion etches, wet etches or electrochemical etches, and the like.

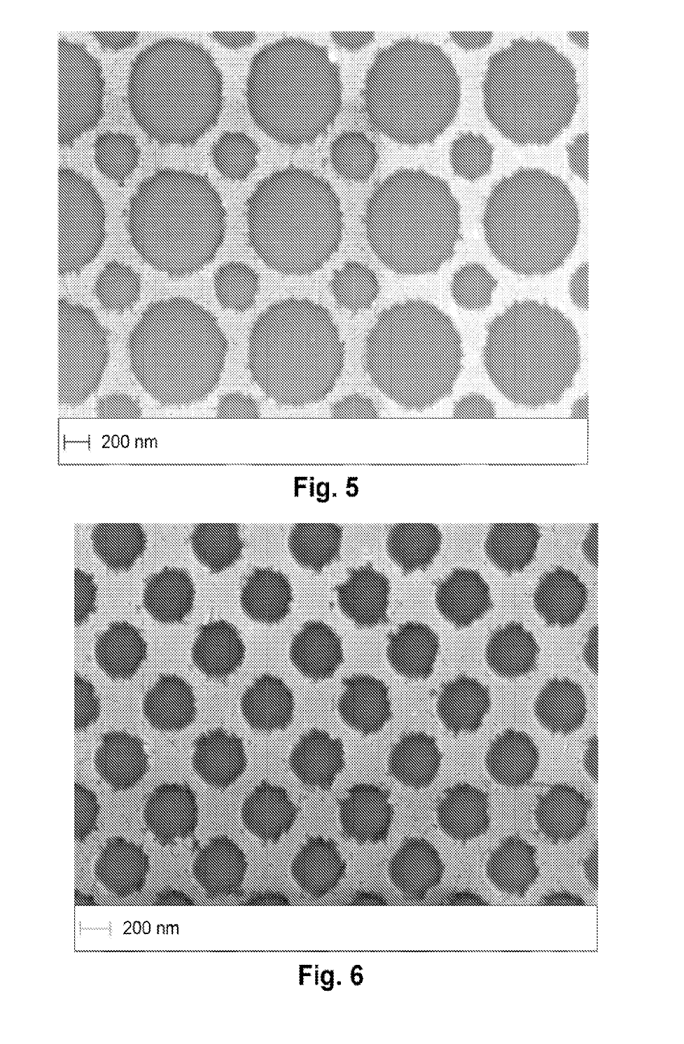

FIGS. 5 and 6 are scanning electron microscope images of two different arrays. Both arrays had aluminum metal layers and silicon oxynitride filling the apertures. The substrate used was silicon. The array of FIG. 5 had two sets of apertures with radii of 383 nm and 192 nm, respectively. The period of the unit cell was 962 nm and the depth of the apertures is 172 nm. The array of FIG. 5 had a single set of apertures with a radius of 192 nm, period of the unit cell was 657 nm, and depth of the apertures was 172 nm.

The above specification, examples and data provide a description of the manufacture and use of the composition of the invention. Since many embodiments of the invention can be made without departing from the spirit and scope of the invention, the invention also resides in the claims hereinafter appended.

What is claimed as new and desired to be protected by Letters Patent of the United States is:

1. A solar cell, comprising:
a solar cell junction arrangement comprising a semiconductor substrate; and
an antireflective conductive layer comprising
a metal layer disposed on the semiconductor substrate and defining at least one array of apertures through the metal layer, wherein each of the apertures has a width of no more than 5 μm and wherein a distance between each aperture and its nearest neighboring aperture is no more than 10 μm, and
a solid material filling each of the apertures, wherein the solid material has an index of refraction of at least 1.1.

2. The solar cell of claim 1, wherein the solid material has an index of refraction of at least 2.

3. The solar cell of claim 1, wherein the solid material is a dielectric material.

4. The solar cell of claim 1, wherein the at least one array of apertures comprises a first array of apertures having a first width and a second array of apertures having a second width, wherein the first width is at least 50 nm less than the second width.

5. The solar cell of claim 1, wherein each of the apertures has a width of at least 100 nm.

6. The solar cell of claim 1, wherein the conductive antireflective layer is an electrical contact for the semiconductor substrate.

7. The solar cell of claim 1, wherein the apertures have an aspect ratio (depth/width) in the range of 0.2 to 5.

8. The solar cell of claim 1, wherein the depth of the apertures is in the range of 50 nm to 5 μm.

9. The solar cell of claim 1, wherein the antireflective conductive layer is configured and arranged to transmit at least 85% of light over a wavelength range extending from 600 nm to 1100 nm.

10. A method of making an antireflective conductive layer on a substrate, the method comprising:
forming a first layer of a first material on the substrate, wherein the first material is non-conductive or semiconductive;
patterning the first layer to form a plurality of posts from the first layer and exposing the substrate between the posts, wherein each of the posts has a width of no more than 5 μm and wherein a distance between each post and its nearest neighboring post is no more than 10 μm;
forming a metal layer over the exposed substrate and the plurality of posts;
removing a portion of the metal layer to expose ends of the plurality of posts and form the antireflective conductive layer.

11. The method of claim 10, wherein removing a portion of the metal layer comprises chemical mechanical polishing of the metal layer.

12. The method of claim 10, wherein patterning the first layer comprises
forming a resist layer over the first layer;
patterning the resist layer to leave portions of the resist layer over portions of the first layer that will firm the plurality of posts; and
removing portions of the first layer based on the patterned resist layer to form the plurality of posts.

13. The method of claim 12, wherein forming, the metal layer comprises forming the metal layer over the exposed substrate, the plurality of posts, and the patterned resist layer; and
wherein removing a portion of the metal layer comprises dissolving the patterned resist layer to remove a portion of the metal layer over the plurality of posts.

14. The method of claim 10, wherein the first material has a dielectric constant of at least 1.1.

15. A method of making an antireflective conductive layer on as substrate, the method comprising:
forming, a metal layer on the substrate;
patterning the metal layer to form a plurality of apertures through the metal layer and exposing the substrate through the apertures, wherein each of the apertures has a width of no more than 5 μm and wherein a distance between each apertures and its nearest neighboring aperture is no more than 10 μm; and
filling the apertures with a first material, wherein the first material is non-conductive or semiconductive.

16. A semiconductor device, comprising:
a semiconductor junction arrangement comprising a semiconductor substrate; and
an antireflective conductive layer comprising
a metal layer disposed on the semiconductor substrate and defining at least one array of apertures through the metal layer, wherein each of the apertures has a width of no more than 5 μm and wherein a distance between each aperture and its nearest neighboring aperture is no more than 10 μm, and
a solid material filling each of the apertures, wherein the solid material has an index of refraction of at least 1.1.

17. The semiconductor device of claim 16, wherein the solid material has an index of refraction of at least 2.

18. The semiconductor device of claim 16, wherein the at least one array of apertures comprises a first array of apertures having a first width and a second array of apertures having a second width, wherein the first width is at least 50 nm less than the second width.

19. The semiconductor device of claim 16, wherein each of the apertures has a width of at least 100 nm.

20. The semiconductor device of claim 16, wherein the conductive antireflective layer is an electrical contact for the semiconductor substrate.

21. The semiconductor device of claim 16, wherein the apertures have an aspect ratio (depth/width) in the range of 0.2 to 5.
